(19) United States
(12) Patent Application Publication
(10) Pub. No.: US 2026/0206444 A1
(43) Pub. Date: Jul. 16, 2026

(54) DISPLAY PANEL AND ELECTRONIC DEVICE INCLUDING THE SAME

(71) Applicant: Samsung Display Co., Ltd., Yongin-si (KR)

(72) Inventors: Seungjae KANG, Yongin-si (KR); Daehwan JANG, Yongin-si (KR)

(73) Assignee: Samsung Display Co., Ltd., Yongin-si (KR)

(21) Appl. No.: 19/426,766

(22) Filed: Dec. 19, 2025

(30) Foreign Application Priority Data
Jan. 13, 2025 (KR) 10-2025-0005040

(51) Int. Cl. H10K 59/131; H10K 59/12; H10K 59/88

(52) U.S. Cl. CPC H10K 59/131; H10K 59/1201; H10K 59/88

(57) ABSTRACT

A display panel includes a signal pad, and the signal pad includes a first conductive pattern connected to a portion of the signal line, a second conductive pattern on the first conductive pattern, and an insulating pattern between the first and second conductive patterns. The insulating pattern includes a main insulating pattern and a dummy insulating pattern spaced apart from the main insulating pattern in a first direction. The second conductive pattern includes a main protruding portion that is on the main insulating pattern and protrudes in a thickness direction and a dummy protruding portion that is on the dummy insulating pattern and protrudes in the thickness direction, and a step difference in the thickness direction between a first peak of the main protruding portion and a second peak of the dummy protruding portion is greater than or equal to 0.3 micrometers.

### CROSS-REFERENCE TO RELATED APPLICATION(S)

This application claims priority to and the benefit of Korean Patent Application No. 10-2025-0005040, filed on Jan. 13, 2025 in the Korean Intellectual Property Office, the disclosure of which is incorporated by reference herein in its entirety.

### BACKGROUND

### 1. Field

The present disclosure relates to display panels and/or electronic devices including the same. More particularly, the present disclosure relates to display panels including a pad area and/or electronic devices including the display panel.

### 2. Description of Related Art

An electronic device includes a display area configured to be activated in response to electrical signals. The electronic device senses external inputs applied from the outside through the display area and displays images to provide a user with information through the display area.

The electronic device includes a display panel and a circuit board. The display panel is connected to a main board via the circuit board. A driving chip is mounted on the display panel.

### SUMMARY

The present disclosure provides a display panel capable of reworking a bonding process and an electronic device including the display panel.

According to an example embodiments of the inventive concepts, a display panel includes a pixel, a signal line electrically connected to the pixel, and a signal pad connected to the signal line. The signal pad includes a first conductive pattern connected to a portion of the signal line, a second conductive pattern on the first conductive pattern, and an insulating pattern between the first conductive pattern and the second conductive pattern. The insulating pattern includes a main insulating pattern and a dummy insulating pattern spaced apart from the main insulating pattern in a first direction. The second conductive pattern includes a main protruding portion and a dummy protrusion portion, the main protruding portion being a first portion of the second conductive pattern that is on the main insulating pattern and protrudes in a thickness direction, the dummy protruding portion being a second portion of the second conductive pattern that is on the dummy insulating pattern and protrudes in the thickness direction, and a first step difference in the thickness direction between a first peak of the main protruding portion and a second peak of the dummy protruding portion is greater than or equal to 0.3 micrometers.

The main insulating pattern includes a first lower surface that is in contact with the first conductive pattern, the dummy insulating pattern includes a second lower surface that is in contact with the first conductive pattern, and a second step difference in the thickness direction between the first lower surface and the second lower surface is greater than or equal to 0.3 micrometers.

The signal pad includes a first pad portion including the main insulating pattern and a second pad portion including the dummy insulating pattern, at least one insulating layer is between the portion of the signal line and the first conductive pattern at the first pad portion, and the first conductive pattern is directly on the portion of the signal line at the second pad portion.

The display panel further includes at least one conductive layer between the portion of the signal line and the first conductive pattern at the first pad portion.

The main insulating pattern and the dummy insulating pattern are inside the first conductive pattern when viewed in a plane.

The main insulating pattern and the dummy insulating pattern are covered by the second conductive pattern.

Each of the first and second conductive patterns includes a first layer, a second layer on the first layer, and a third layer on the second layer, and a conductivity of the second layer is greater than a conductivity of the first layer and a conductivity of the third layer.

The insulating pattern includes a polymer.

According to an example embodiments of the inventive concepts, an electronic device includes a display panel including a pixel, a signal line electrically connected to the pixel, and a signal pad connected to the signal line, an electronic component including a bump electrode and electrically connected to the display panel, and an adhesive layer attaching the electronic component to the display panel. The signal pad includes a first conductive pattern connected to a portion of the signal line, a second conductive pattern on the first conductive pattern, and an insulating pattern between the first conductive pattern and the second conductive pattern. The insulating pattern includes a main insulating pattern and a dummy insulating pattern spaced apart from the main insulating pattern in a first direction. The main insulating pattern includes a first lower surface that is in contact with the first conductive pattern, the dummy insulating pattern includes a second lower surface that is in contact with the first conductive pattern, and a step difference in a thickness direction of the insulating pattern between the first lower surface and the second lower surface is greater than or equal to 0.3 micrometers.

The signal pad includes a first pad portion including the main insulating pattern and a second pad portion including the dummy insulating pattern, at least one insulating layer is between the portion of the signal line and the first conductive pattern at the first pad portion, and the first conductive pattern is directly on the portion of the signal line at the second pad portion.

The electronic device further includes at least one conductive layer between the portion of the signal line and the first conductive pattern at the first pad portion.

The second conductive pattern includes a main protruding portion and a dummy protruding portion, the main protruding portion being a first portion of the second conductive pattern that is on the main insulating pattern and protrudes in the thickness direction, the dummy protruding portion being a second portion of the second conductive pattern that is on the dummy insulating pattern and protrudes in the thickness direction.

The bump electrode overlaps the main insulating pattern when viewed in a plane, the bump electrode is in contact with the main protruding portion and is electrically connected to the main protruding portion, and the bump electrode is not in contact with the dummy protruding portion.

The bump electrode overlaps at least a portion of the dummy insulating pattern when viewed in the plane.

The main insulating pattern has a thickness smaller than a thickness of the dummy insulating pattern.

The bump electrode does not overlap the main insulating pattern and overlaps the dummy insulating pattern when viewed in the plane, the bump electrode is not in contact with the main protruding portion, and the bump electrode is in contact with the dummy protruding portion and is electrically connected to the dummy protruding portion.

The main insulating pattern has a same thickness as a thickness of the dummy insulating pattern.

The main insulating pattern and the dummy insulating pattern are inside the first conductive pattern when viewed in the plane.

The main insulating pattern and the dummy insulating pattern are covered by the second conductive pattern.

The insulating pattern includes a polymer.

According to the above, the signal pads of the display panel include the main insulating pattern and the dummy insulating pattern that are arranged with a step difference. Accordingly, the bonding process is able to be reworked when desired, thereby improving overall processability of the signal pads of the display panel.

### BRIEF DESCRIPTION OF THE DRAWINGS

FIG. 1 is a perspective view of a display device according to an example embodiment of the present disclosure;

FIGS. 2A and 2B are exploded perspective views of a display device according to an example embodiment of the present disclosure;

FIG. 3 is a cross-sectional view of a display module according to an example embodiment of the present disclosure;

FIG. 4 is a plan view of a display panel according to an example embodiment of the present disclosure;

FIG. 5 is a cross-sectional view of a pixel according to an example embodiment of the present disclosure;

FIG. 6 is an enlarged perspective view of a pad area of a display device according to an example embodiment of the present disclosure;

FIG. 7A is a plan view of a pad area according to an example embodiment of the present disclosure;

FIGS. 7B and 7C are cross-sectional views of a pad area according to some example embodiments of the present disclosure;

FIG. 8A is a cross-sectional view of a structure of a display device before a bonding process, according to an example embodiment of the present disclosure;

FIG. 8B is a cross-sectional view of a structure of a display device after a bonding process, according to an example embodiment of the present disclosure;

FIG. 9A is a cross-sectional view of a structure of a display device before a bonding process, according to an example embodiment of the present disclosure;

FIG. 9B is a cross-sectional view of a structure of a display device after a bonding process, according to an example embodiment of the present disclosure;

FIGS. 10A to 10D are plan views of pad areas according to some example embodiments of the present disclosure;

FIG. 11 is a block diagram of an electronic device according to an example embodiment of the present disclosure; and

FIG. 12 is a schematic view of various electronic devices according to some example embodiments of the present disclosure.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, some example embodiments of the present disclosure will be described with reference to accompanying drawings.

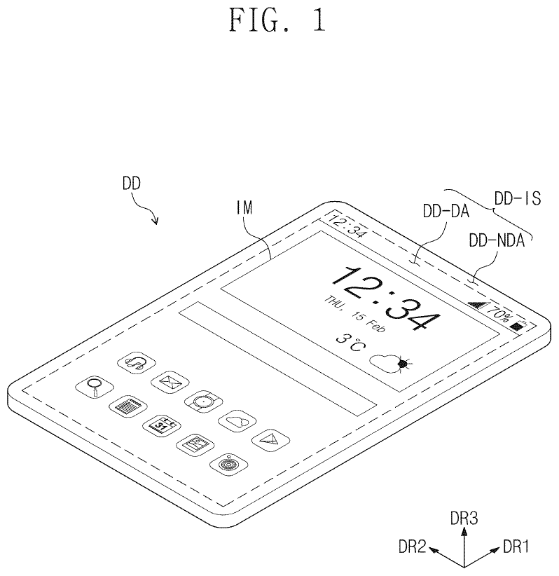

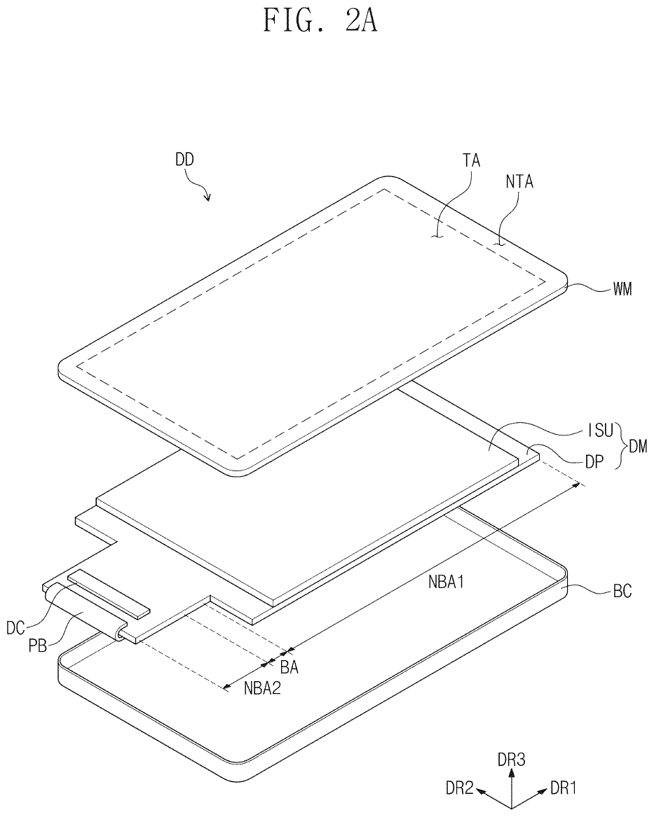

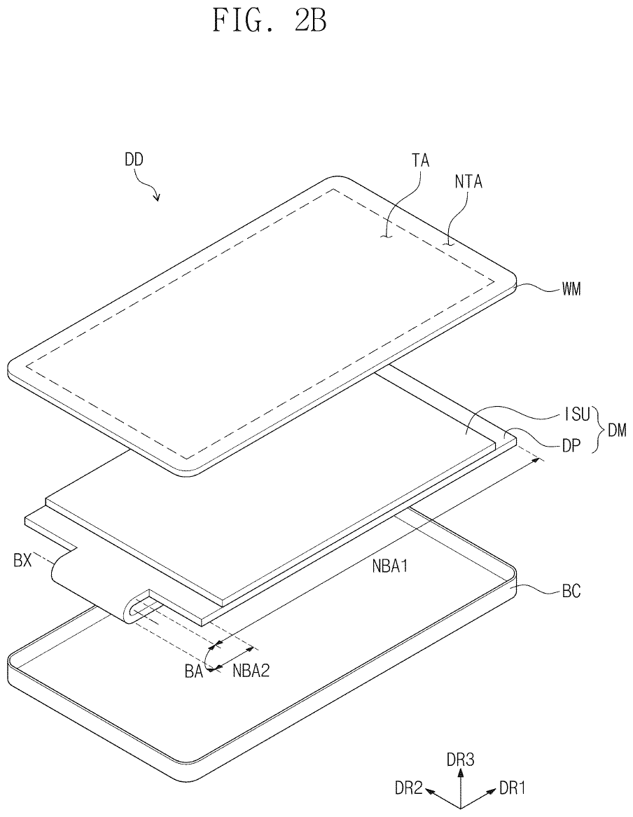

FIG. 1 is a perspective view of a display device DD according to an example embodiment of the present disclosure. FIGS. 2A and 2B are exploded perspective views of the display device DD according to an example embodiment of the present disclosure. FIG. 2B illustrates the display device DD whose bending area BA shown in FIG. 2A is bent.

Referring to FIG. 1, a mobile phone terminal is shown as a representative example of the display device DD. The display device DD according to the present disclosure may be applied to a large-sized electronic device, such as a television set, a monitor, etc., and a small and medium-sized electronic device, such as a tablet computer, a car navigation unit, a game unit, a smart watch, etc.

The display device DD may have a rectangular shape with long sides extending in a first direction DR1 and short sides extending in a second direction DR2 intersecting the first direction DR1. However, the shape of the display device DD should not be limited to the rectangular shape, and the display device DD may have a variety of shapes, such as a circular shape, a polygonal shape, etc.

Hereinafter, a direction substantially perpendicular to a plane defined by the first direction DR1 and the second direction DR2 may be referred to as a third direction DR3. In the present disclosure, the expression “when viewed in a plane” may mean a state of being viewed in the third direction DR3.

The display device DD may be rigid or flexible. The term “flexible” used herein refers to the property of being able to be bent, and the display device DD may include all structures from a structure that is completely bent to a structure that is bent at the scale of a few nanometers. For example, the flexible display device DD may be a curved display device, a rollable display device, or a foldable display device.

The display device DD may display an image through a display surface DD-IS. FIG. 1 shows application icons as a representative example of the image IM. The display surface DD-IS may be substantially parallel to the plane defined by the first direction DR1 and the second direction DR2.

The display surface DD-IS may include a display area DD-DA through which the image is displayed and a non-display area DD-NDA adjacent to the display area DD-DA. The image may not be displayed through the non-display area DD-NDA. According to an example embodiment, the non-display area DD-NDA may be disposed adjacent to only one side of the display area DD-DA or may be omitted.

Referring to FIGS. 2A and 2B, the display device DD may include a window WM, a display module DM, and an accommodation member BC.

The window WM may be disposed on the display module DM and may transmit an image provided from the display module DM to the outside thereof. Although not shown in figures, the window WM may include a base layer and functional layers disposed on the base layer. The functional layers may include a protective layer, an anti-fingerprint layer, etc. The base layer of the window WM may include a glass, sapphire, or plastic material. The base layer of the window WM may include an optically transparent insulating material. As an example, the base layer of the window WM may include a glass or plastic film or may include a glass substrate and a plastic film coupled to the glass substrate by an adhesive.

The window WM may include a transmission area TA and a non-transmission area NTA. The transmission area TA may overlap the display area DD-DA shown in FIG. 1 and may have a shape corresponding to that of the display area DD-DA. The non-transmission area NTA may overlap the non-display area DD-NDA shown in FIG. 1 and may have a shape corresponding to that of the non-display area DD-NDA. The non-transmission area NTA may have a relatively low light transmittance compared to that of the transmission area TA. The non-transmission area NTA may be defined in an area of the base layer of the window WM by a bezel pattern, and an area of the base layer in which the bezel pattern is not disposed may be defined as the transmission area TA. However, example embodiments of the present disclosure may not be limited thereto or thereby, and the non-transmission area NTA may be omitted.

Although not shown in figures, an anti-reflective layer may be further disposed between the window WM and the display module DM. The anti-reflective layer may reduce a reflectance of an external light incident thereto from the outside of the display device DD. The anti-reflective layer may include color filters. The color filters may be arranged in a selected arrangement. As an example, the color filters may be arranged by taking into account of colors of lights emitted from pixels included in a display panel DP. In addition, the anti-reflective layer may further include a black matrix adjacent to the color filters.

The display module DM may include the display panel DP and an input sensor ISU.

The display panel DP may be one of a liquid crystal display panel, an electrophoretic display panel, a microelectromechanical system (MEMS) display panel, an electrowetting display panel, an organic light emitting display panel, an inorganic light emitting display panel, or a quantum dot light emitting display panel, and it should not particularly limited. Hereinafter, the organic light emitting display panel will be described as the display panel DP.

The input sensor ISU may include one of a capacitive sensor, an optical sensor, an ultrasonic sensor, or an electromagnetic induction sensor. The input sensor ISU may be formed on the display panel DP through successive processes or may be attached to an upper portion of the display panel DP using an adhesive layer after being separately manufactured. However, example embodiments of the present disclosure should not be limited thereto or thereby.

The display device DD may further include a driving chip DC disposed on the display panel DP. The display device DD may further include a circuit board PB disposed on the display panel DP. In the present example embodiment, the circuit board PB may be a flexible circuit board. However, example embodiments of the present disclosure should not be limited thereto or thereby. As an example, the circuit board PB may be rigid. The circuit board PB may electrically connect the display panel DP and a main circuit board.

The driving chip DC may include driving elements (e.g., a data driving circuit) to drive pixels of the display panel DP. FIG. 2A shows a structure in which the driving chip DC is mounted on the display panel DP. However, example embodiments of the present disclosure should not be limited thereto or thereby. As an example, the driving chip DC may be mounted on the circuit board PB. In the present example embodiment, the driving chip DC and the circuit board PB, which are directly mounted on the display panel DP, may be collectively referred to as “electronic components”.

The display panel DP may include a bending area BA, a first non-bending area NBA1, and a second non-bending area NBA2 spaced apart the first non-bending area NBA1 in the first direction DR1, and the bending area BA may be disposed between the first non-bending area NBA1 and the second non-bending area NBA2.

The bending area BA may be a portion of the display panel DP, which is bent with respect to an imaginary bending axis BX extending in the second direction DR2. The first non-bending area NBA1 may overlap the transmission area TA, and the second non-bending area NBA2 may be defined as an area to which the circuit board PB is connected. When the bending area BA of the display panel DP is bent with respect to the bending axis BX, the circuit board PB and the driving chip DC may be bent in a direction toward a rear surface of the display panel DP and/or may be disposed under the display panel DP. Although not shown in figures, additional components may be provided to the display device DD to compensate for a step difference caused by the bending area BA between the circuit board PB and the rear surface of the display panel DP.

According to an example embodiment, a width in the second direction DR2 of the first non-bending area NBA1 may be greater than a width in the second direction DR2 of the bending area BA and the second non-bending area NBA2. However, example embodiments of the present disclosure should not be limited thereto or thereby. According to an example embodiment, the width in the second direction DR2 of the bending area BA may gradually decrease from the first non-bending area NBA1 to the second non-bending area NBA2. However, example embodiments of the present disclosure should not be limited thereto or thereby.

As shown in FIG. 2B, as the portion of the display panel DP is bent, the circuit board PB electrically bonded to the display panel DP may be disposed on the rear surface of the display panel DP.

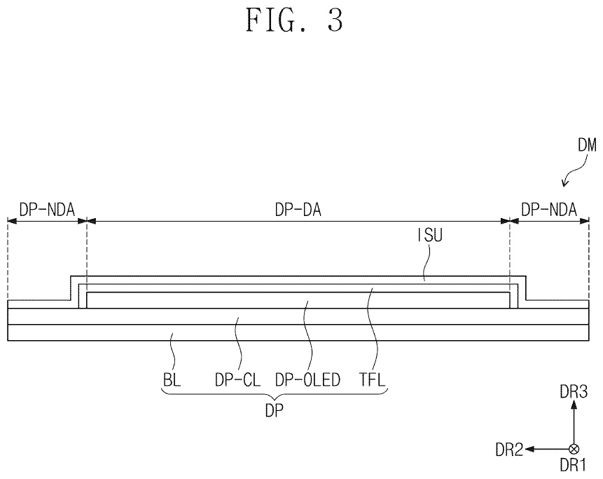

The accommodation member BC may accommodate the display module DM and may be coupled to the window WM. The circuit board PB may be disposed at one end of the display panel DP and may be electrically connected to a circuit element layer DP-CL (refer to FIG. 3). Although not shown in figures, the display device DD may further include a main board, electronic modules mounted on the main board, a camera module, a power module, or the like.

In the present example embodiment, the mobile phone terminal is described as a representative example of the display device DD, however, the display device DD should not be particularly limited as long as the display device DD includes two or more electronic components bonded to each other. The display panel DP and the driving chip DC mounted on the display panel DP may correspond to different electronic parts, and the display device DD may be configured to include only the display panel DP and the driving chip DC. However, example embodiments of the present disclosure should not be particularly limited thereto. The display panel DP and the circuit board PB connected to the display panel DP may correspond to different electronic components, and the display device DD may be configured to include only the display panel DP and the circuit board PB. In addition, the display device DD may be configured to include only the main board and the electronic module mounted on the main board. Hereinafter, descriptions on the display device DD will focus on a bonding structure between the display panel DP and the driving chip DC mounted on the display panel DP.

FIG. 3 is a cross-sectional view of the display module DM according to an example embodiment of the present disclosure.

Referring to FIG. 3, the display panel DP may include a base layer BL, the circuit element layer DP-CL, a display element layer DP-OLED, and an upper insulation layer TFL, which are sequentially stacked on the base layer BL. The input sensor ISU may be disposed on the upper insulation layer TFL.

The display panel DP may include a display area DP-DA and a non-display area DP-NDA. The display area DP-DA of the display panel DP may correspond to the display area DD-DA shown in FIG. 1 or the transmission area TA shown in FIG. 2A, and the non-display area DP-NDA may correspond to the non-display area DD-NDA shown in FIG. 1 or the non-transmission area NTA shown in FIG. 2A.

The base layer BL may include at least one plastic film. The base layer BL may be a flexible substrate and may include a plastic substrate, a glass substrate, a metal substrate, or an organic/inorganic composite material substrate.

The circuit element layer DP-CL may include at least one intermediate insulating layer and a circuit element. The intermediate insulating layer may include at least one intermediate inorganic layer and at least one intermediate organic layer. The circuit element may include signal lines and a pixel driving circuit. An insulating layer, a semiconductor layer, and a conductive layer may be formed by coating and deposition processes. Then, the insulating layer, the semiconductor layer, and the conductive layer may be selectively patterned by a photolithography process and an etching process. A semiconductor pattern, a conductive pattern, and the signal line may be formed by the above-mentioned processes. Patterns disposed at the same layer may be formed through the same process. The expression “the patterns are formed through the same process,” as used herein, means that the patterns include the same material and have the same stack structure.

The display element layer DP-OLED may include a plurality of organic light emitting elements. The display element layer DP-OLED may further include an organic layer such as a pixel definition layer.

The upper insulation layer TFL may encapsulate the display element layer DP-OLED. The upper insulation layer TFL may be disposed on the display element layer DP-OLED. The upper insulation layer TFL may overlap the display area DP-DA and the non-display area DP-NDA. The upper insulation layer TFL may overlap at least a portion of the non-display area DP-NDA. As an example, the upper insulation layer TFL may include a thin film encapsulation layer. The thin film encapsulation layer may have a stack structure of an inorganic layer/organic layer/inorganic layer. The upper insulation layer TFL may protect the display element layer DP-OLED from moisture, oxygen, and/or a foreign substance such as dust particles. However, example embodiments of the present disclosure should not be limited thereto or thereby. According to an example embodiment, the upper insulation layer TFL may further include an additional insulating layer in addition to the thin film encapsulation layer. For instance, the upper insulation layer TFL may further include an optical insulating layer to control a refractive index.

According to an example embodiment, a sealing substrate may be provided instead of the upper insulation layer TFL. In this case, the sealing substrate may face the base layer BL, and the circuit element layer DP-CL and the display element layer DP-OLED may be disposed between the sealing substrate and the base layer BL.

The input sensor ISU may be disposed directly on the display panel DP. In the present disclosure, the expression “a component A is disposed directly on a component B” means that no intervening elements are present between the component A and the component B. In the present example embodiment, the input sensor ISU may be formed through successive processes with the display panel DP. However, example embodiments of the present disclosure should not be limited thereto or thereby. According to an example embodiment, the input sensor ISU may be provided as an individual panel and then may be coupled to the display panel DP by an adhesive layer. According to an example embodiment, the input sensor ISU may be omitted.

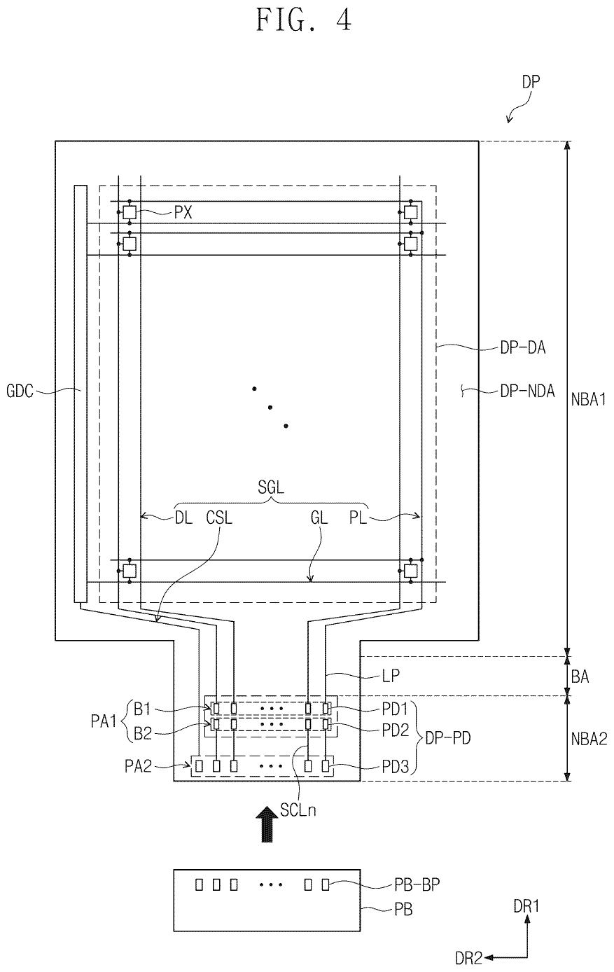

FIG. 4 is a plan view of the display panel DP according to an example embodiment of the present disclosure.

Referring to FIG. 4, the display panel DP may include a plurality of pixels PX, a gate driving circuit GDC, a plurality of signal lines SGL, and a plurality of signal pads DP-PD. PD.

The pixels PX may be arranged in the display area DP-DA. Each of the pixels PX may include a light emitting element and a pixel driving circuit connected to the light emitting element. The gate driving circuit GDC may sequentially output gate signals to a plurality of gate lines GL described later. The gate driving circuit GDC may include a transistor formed through the same process as a transistor of the pixel PX, for example, a low temperature polycrystalline silicon (LTPS) process or a low temperature polycrystalline oxide (LTPO) process. The display panel DP may further include another driving circuit that applies a light emission control signal to the pixels PX.

The signal lines SGL may include the gate lines GL, data lines DL, a power line PL, and a control signal line CSL. Each of the gate lines GL may be connected to a corresponding pixel PX among the pixels PX, and each of the data lines DL may be connected to a corresponding pixel PX among the pixels PX. The power line PL may be connected to the pixels PX. The control signal line CSL may be connected to the gate driving circuit GDC and may provide control signals to the gate driving circuit GDC.

The signal lines SGL may overlap the display area DP-DA and the non-display area DP-NDA. Each of the signal lines SGL may include a line part LP. Although not shown in figures, the signal lines SGL may further include a pad part. The line part LP may overlap the display area DP-DA and the non-display area DP-NDA. The pad part may be connected to an end of the line part LP.

The signal pads DP-PD may include first pads PD1, second pads PD2, and third pads PD3. An area in which the first pads PD1 and the second pads PD2 are arranged may be referred to as a first pad area PA1, and an area in which the third pads PD3 are arranged may be referred to as a second pad area PA2.

The first pad area PA1 may be an area overlapping the driving chip DC of FIG. 2A, and the second pad area PA2 may be an area overlapping the circuit board PB of FIG. 2A. The first pad area PA1 may include a first area B1 in which the first pads PD1 are arranged and a second area B2 in which the second pads PD2 are arranged. The first pad area PA1 and the second pad area PA2 may be disposed in the non-display area DP-NDA. The first pad area PA1 and the second pad area PA2 may be spaced apart from each other in the first direction DR1. One pad row is arranged in the second pad area PA2 as a representative example, however, example embodiments of the present disclosure should not be limited thereto or thereby. In some example embodiments, a plurality of pad rows may be arranged in the second pad area PA2.

Each of the first pads PD1 may be connected to a corresponding data line DL among the data lines DL. Although not shown in figures, the first pads PD1 and the second pads PD2 may be electrically connected to each other. The second pads PD2 may be connected to the third pads PD3 via connection signal lines SCLn.

The circuit board PB may include a plurality of substrate bump electrodes PB-BP. The substrate bump electrodes PB-BP may be arranged in the second direction DR2. The substrate bump electrodes PB-BP of the circuit board PB may be connected to the third pads PD3 of the second pad area PA2.

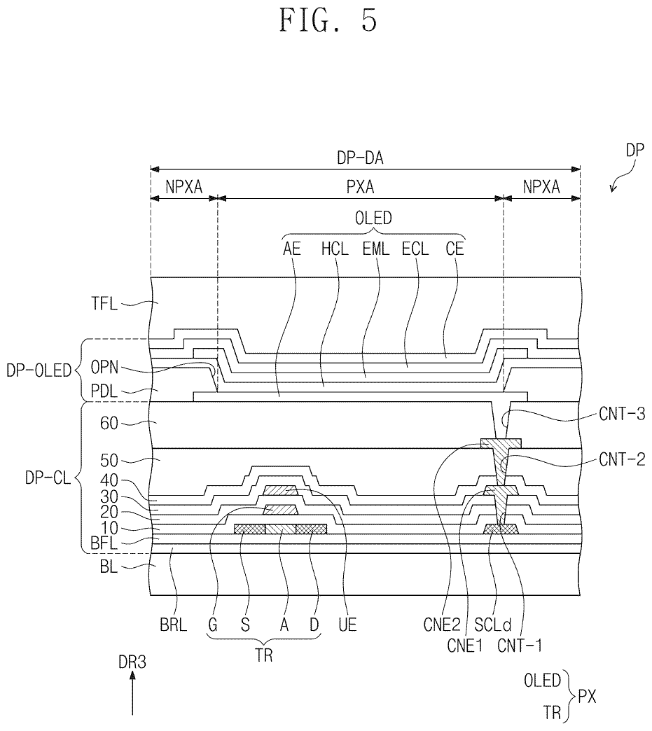

FIG. 5 is a cross-sectional view of the pixel PX of the display panel DP according to an example embodiment of the present disclosure.

Referring to FIG. 5, the display area DP-DA may include a light emitting area PXA and a non-light-emitting area NPXA. Each of the pixels PX may include the light emitting element OLED and the pixel driving circuit connected to the light emitting element OLED. For example, the pixel PX may include the transistor TR and the light emitting element OLED.

FIG. 5 shows only one transistor TR as a representative example, however, example embodiments of the present disclosure should not be limited thereto or thereby. As an example, the pixel PX may include seven transistors and at least one capacitor, and the seven transistors and the capacitor may be electrically connected to each other. However, the number of the transistors and the number of the capacitors, which form the pixel PX, should not be particularly limited.

The display panel DP may include a plurality of insulating layers, a semiconductor pattern, a conductive pattern, and a signal line. An insulating layer, a semiconductor layer, and a conductive layer may be formed by coating and deposition processes. Then, the insulating layer, the semiconductor layer, and the conductive layer may be selectively patterned by a photolithography process. The semiconductor pattern, the conductive pattern, and the signal line, which are included in the circuit element layer DP-CL and the display element layer DP-OLED, may be formed by the above-mentioned method.

The base layer BL may include a synthetic resin film. The base layer BL may have a multi-layer structure. For instance, the base layer BL may have a three-layer structure of a synthetic resin layer, an inorganic layer, and a synthetic resin layer. The synthetic resin layer may include a polyimide-based resin, however, example embodiments of the present disclosure should not be particularly limited thereto. In some example embodiments, the base layer BL may include a glass substrate, a metal substrate, or an organic/inorganic composite substrate.

The circuit element layer DP-CL may include a barrier layer BRL, a buffer layer BFL, first, second, third, fourth, fifth, and sixth insulating layers 10, 20, 30, 40, 50, and 60, the transistor TR, a connection signal line SCLd, an upper electrode UE, a first connection electrode CNE1, and a second connection electrode CNE2.

At least one inorganic layer may be disposed on an upper surface of the base layer BL. The inorganic layer may have a multi-layer structure. For example, the barrier layer BRL may be disposed on the base layer BL, and the buffer layer BFL may be disposed on the barrier layer BRL. Each of the barrier layer BRL and the buffer layer BFL may be an inorganic layer.

The semiconductor pattern may be disposed on the buffer layer BFL. The semiconductor pattern may include polycrystalline silicon, however, example embodiments of the present disclosure should not be limited thereto or thereby. According to an example embodiment, the semiconductor pattern may include amorphous silicon or metal oxide.

FIG. 5 shows a portion of the semiconductor pattern, and the semiconductor pattern may be further disposed in other areas of the pixel PX when viewed in the plane. The semiconductor pattern may be arranged with a specific rule over the pixels PX. The semiconductor pattern may have different electrical properties depending on whether it is doped or not. The semiconductor pattern may include a first region and a second region. The first region may be doped with an N-type dopant or a P-type dopant. A P-type transistor may include a doped area doped with the P-type dopant.

The first region may have a conductivity greater than that of the second region and may substantially serve as an electrode or a signal line. The second region may be a non-doped region or a region with a low doping concentration and may substantially correspond to an active (or a channel) of the transistor. A portion of the semiconductor pattern may be the active of the transistor, another portion of the semiconductor pattern may be a source or a drain of the transistor, and the other portion of the semiconductor pattern may be a connection electrode or a connection signal line.

As shown in FIG. 5, a source S, an active A, and a drain D of the transistor TR may be formed from the semiconductor pattern.

FIG. 5 shows a portion of the connection signal line SCLd formed from the semiconductor pattern. The connection signal line SCLd may be electrically connected to a drain of one of the transistors of the pixel PX.

The first insulating layer 10 may be disposed on the buffer layer BFL. The first insulating layer 10 may cover the semiconductor pattern. The first insulating layer 10 may commonly overlap the pixels PX. A gate G may be disposed on the first insulating layer 10. The gate G may be a portion of a metal pattern. The gate G may overlap the active A. The gate G may be used as a mask in a process of doping the semiconductor pattern.

The second insulating layer 20 may be disposed on the first insulating layer 10 and may cover the gate G. The second insulating layer 20 may commonly overlap the pixels PX. The upper electrode UE may be disposed on the second insulating layer 20. The upper electrode UE may overlap the gate G of the transistor TR. The upper electrode UE may be a portion of a metal pattern. A portion of the gate G and the upper electrode UE overlapping the portion of the gate G may define a capacitor.

The third insulating layer 30 may be disposed on the second insulating layer 20 and may cover the upper electrode UE. The first connection electrode CNE1 disposed on the third insulating layer 30 may be connected to the connection signal line SCLd via a contact hole CNT-1 defined through the first, second, and third insulating layers 10, 20, and 30.

The fourth insulating layer 40 may be disposed on the third insulating layer 30 and may cover the first connection electrode CNE1. The first to fourth insulating layers 10 to 40 may be an inorganic layer and/or an organic layer and may have a single-layer or multi-layer structure.

According to an example embodiment, the first connection electrode CNE1 may be disposed on the fourth insulating layer 40 and may be covered by the fifth insulating layer 50. According to an example embodiment, the display panel DP may include both the first connection electrode disposed on the third insulating layer 30 and covered by the fourth insulating layer 40 and the first connection electrode disposed on the fourth insulating layer 40 and covered by the fifth insulating layer 50.

The fifth insulating layer 50 may be disposed on the fourth insulating layer 40. The fifth insulating layer 50 may be an organic layer. The second connection electrode CNE2 may be disposed on the fifth insulating layer 50. The second connection electrode CNE2 may be connected to the first connection electrode CNE1 via a contact hole CNT-2 defined through the fourth and fifth insulating layers 40 and 50.

The sixth insulating layer 60 may be disposed on the fifth insulating layer 50 and may cover the second connection electrode CNE2. The sixth insulating layer 60 may be an organic layer. A first electrode AE may be disposed on the sixth insulating layer 60. The first electrode AE may be connected to the second connection electrode CNE2 via a contact hole CNT-3 defined through the sixth insulating layer 60.

The circuit element layer DP-CL may include a plurality of connection electrodes connected to the transistors, and some of the connection electrodes may be disposed at different layers. Although not shown in figures, the first connection electrode CNE1 may be extended and connected to the transistor TR. Locations of the connection electrodes should not be particularly limited.

The display element layer DP-OLED may include the pixel definition layer PDL and the light emitting element OLED. A pixel opening OPN may be defined through the pixel definition layer PDL. At least a portion of the first electrode AE may be exposed through the pixel opening OPN of the pixel definition layer PDL. In the present example embodiment, the light emitting area PXA may be defined to correspond to a portion of the first electrode AE, which is exposed through the pixel opening OPN.

A hole control layer HCL may be commonly disposed in the light emitting area PXA and the non-light-emitting area NPXA. The hole control layer HCL may include a hole transport layer and/or a hole injection layer. A light emitting layer EML may be disposed on the hole control layer HCL. The light emitting layer EML may be disposed in an area corresponding to the pixel opening OPN. That is, the light emitting layer EML may be divided into portions, and the divided portions of the light emitting layer EML may be disposed in the pixels PX, respectively. However, example embodiments of the present disclosure should not be limited thereto or thereby. According to an example embodiment, the light emitting layer EML may be commonly formed over the plural pixels PX using an open mask.

An electron control layer ECL may be disposed on the light emitting layer EML. The electron control layer ECL may include an electron transport layer and/or an electron injection layer. The hole control layer HCL and the electron control layer ECL may be commonly formed over the plural pixels PX using an open mask. A second electrode CE may be disposed on the electron control layer ECL. The second electrode CE may have an integral shape and may be commonly disposed in the pixels PX. The upper insulation layer TFL may be disposed on the second electrode CE. The upper insulation layer TFL may include a plurality of thin film layers.

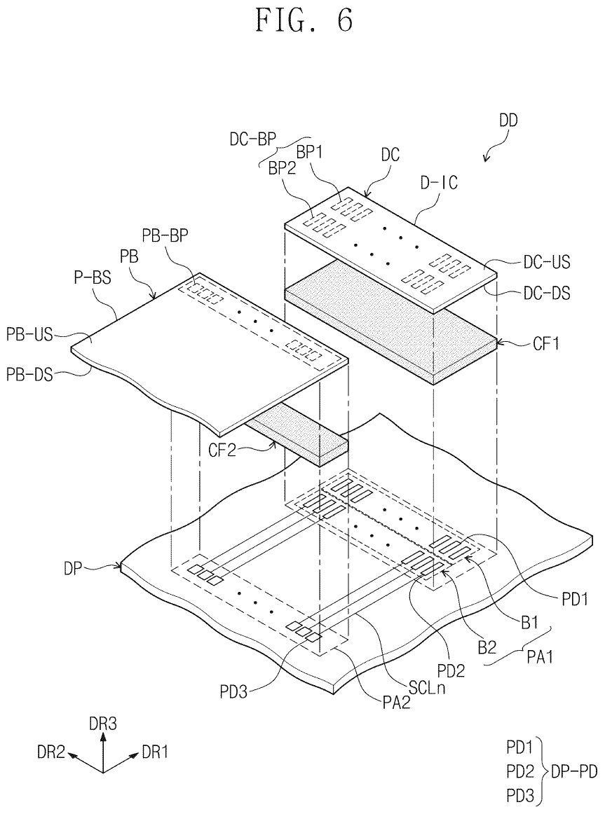

FIG. 6 is an enlarged perspective view of pad areas PA1 and PA2 of the display device DD according to an example embodiment of the present disclosure. In FIG. 6, the driving chip DC and the circuit board PB are shown as being separated from the display panel DP as an example. Because the first pads PD1, the second pads PD2, the connection signal lines SCLn, and the third pads PD3 are the same as the first pads PD1, the second pads PD2, the connection signal lines SCLn, and the third pads PD3 of FIG. 4, details thereof will be omitted.

Referring to FIGS. 4 and 6, the driving chip DC may be bonded to the first pad area PA1 by a first adhesive layer CF1. The circuit board PB may be bonded to the second pad area PA2 by a second adhesive layer CF2. The first adhesive layer CF1 and the second adhesive layer CF2 may include a synthetic resin with an adhesive property. Each of the first adhesive layer CF1 and the second adhesive layer CF2 may be a non-conductive film. That is, the first adhesive layer CF1 and the second adhesive layer CF2 may not include conductive balls but may include only the synthetic resin with the adhesive property.

The driving chip DC may include a driving integrated circuit D-IC and chip bump electrodes DC-BP provided in the driving chip DC. The driving integrated circuit D-IC may include an upper surface DC-US and a lower surface DC-DS, and the lower surface DC-DS may face the first and second pads PD1 and PD2. The chip bump electrodes DC-BP may be disposed on the lower surface DC-DS of the driving integrated circuit D-IC.

The chip bump electrodes DC-BP may include first bumps BP1 electrically connected to the first pads PD1, respectively, and second bumps BP2 electrically connected to the second pads PD2, respectively. The first bumps BP1 may be arranged in the second direction DR2, and the second bumps BP2 may be spaced apart from the first bumps BP1 in the first direction DR1 and may be arranged in the second direction DR2.

The driving chip DC may receive first signals from the outside via the second pads PD2 and the second bumps BP2. The driving chip DC may apply second signals, which are generated based on the first signals, to the first pads PD1 via the first bumps BP1. As an example, the driving chip DC may include a data driving circuit. The first signal may be an image signal that is a digital signal provided from the outside, and the second signal may be a data signal that is an analog signal. The driving chip DC may generate an analog voltage corresponding to a grayscale value of the image signal. The data signal may be applied to the pixel PX via the data line DL shown in FIG. 4.

Although not shown in FIG. 6, the first bumps BP1 and the second bumps BP2 may protrude from the lower surface DC-DS of the driving integrated circuit D-IC and may be exposed to the outside. When the first adhesive layer CF1 is cured, the first pads PD1 may be attached to and fixed to the first bumps BP1, and the second pads PD2 may be attached to and fixed to the second bumps BP2.

The circuit board PB may include a base layer P-BS and the substrate bump electrodes PB-BP provided in the circuit board PB. The circuit board PB may include an upper surface PB-US and a lower surface PB-DS, and the lower surface PB-DS may face the third pads PD3. The substrate bump electrodes PB-BP may be disposed on the lower surface PB-DS of the circuit board PB. The substrate bump electrodes PB-BP may be electrically connected to the third pads PD3, respectively. The substrate bump electrodes PB-BP may be arranged in the second direction DR2. The circuit board PB may provide image signals, driving voltages, and other control signals to the driving chip DC.

Although not shown in FIG. 6, the substrate bump electrodes PB-BP may protrude from the lower surface PB-DS of the base layer P-BS and may be exposed to the outside. When the second adhesive layer CF2 is cured, the third pads PD3 may be attached to and fixed to the substrate bump electrodes PB-BP.

The electronic component may include a substrate and a bump electrode disposed under the substrate. In a case where the electronic component corresponds to the driving chip DC, the substrate may correspond to the driving integrated circuit D-IC of the driving chip DC, and the bump electrode may correspond to the chip bump electrode DC-BP. According to an example embodiment, in a case where the electronic component corresponds to the circuit board PB, the substrate may correspond to the base layer P-BS of the circuit board PB, and the bump electrode may correspond to the substrate bump electrode PB-BP.

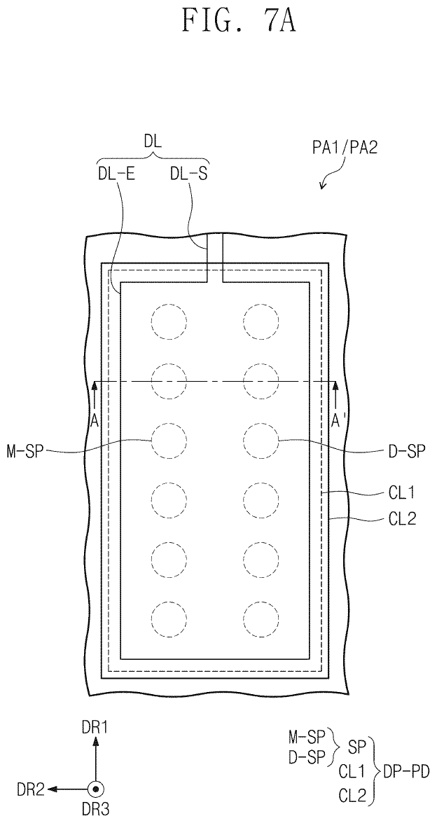

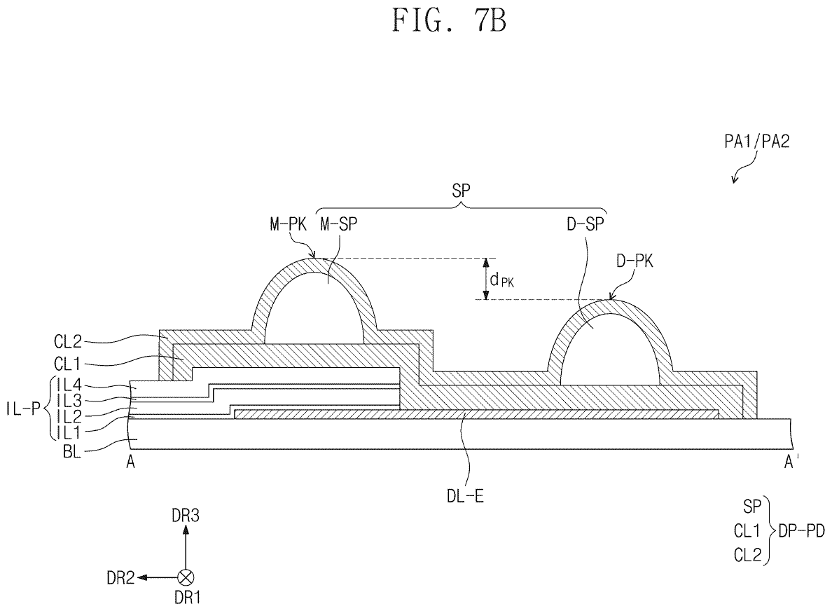

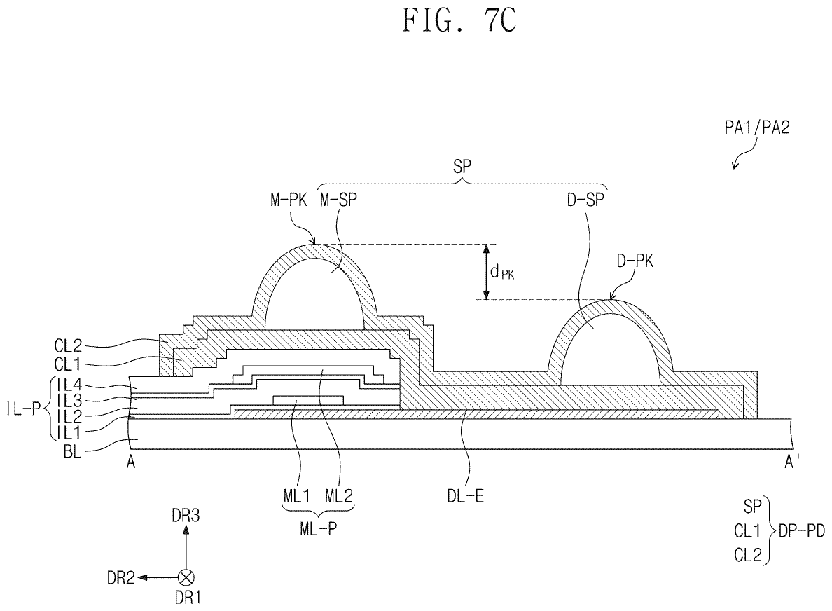

FIG. 7A is a plan view of the pad areas PA1 and PA2 according to an example embodiment of the present disclosure. FIGS. 7B and 7C are cross-sectional views of pad areas PA1 and PA2 according to some example embodiments of the present disclosure. FIG. 7B is a cross-sectional view taken along a line A-A′ of FIG. 7A according to an example embodiment of the present disclosure, and FIG. 7C is a cross-sectional view taken along the line A-A′ of FIG. 7A according to an example embodiment of the present disclosure.

The signal pad DP-PD (or a signal pad structure) shown in FIGS. 7A to 7C may be one of the first to third pads PD1 to PD3 described with reference to FIGS. 4 and 6. FIG. 7A shows the data line DL including an end portion DL-E and a line portion DL-S, which have different widths, as a representative example of the signal line, however, example embodiments of the present disclosure are not limited thereto or thereby. In the present example embodiment, the width may refer to a length or width in the second direction DR2 of the end portion DL-E or the line portion DL-S. The signal line may be a signal line other than the data line DL and may have a uniform width without distinguishing between the end portion DL-E and the line portion DL-S. The end portion DL-E may correspond to the pad portion described with reference to FIG. 4. The end portion DL-E may be referred to as a portion of the signal line.

Hereinafter, descriptions on the pad areas PA1 and PA2 will focus on the first pad area PA1 in which the data line DL is disposed. The descriptions on the first pad area PA1 may be equally applied to the second pad area PA2 except that the connection signal line SCLn (refer to FIG. 4) is disposed instead of the data line DL in the second pad area PA2.

Referring to FIG. 7A, the signal pad DP-PD may include a first conductive pattern CL1, a second conductive pattern CL2, and at least one insulating pattern SP. FIG. 7A shows the signal pad DP-PD including twelve insulating patterns SP as a representative example, however, the number of the insulating patterns SP are not particularly limited.

When viewed in the plane, the end portion DL-E may have a shape that extends in the first direction DR1. That is, the end portion DL-E may have a length or width in the first direction DR1 that is greater than a length or width in the second direction DR2.

When viewed in the plane, the insulating patterns SP may overlap the first conductive pattern CL1 and the second conductive pattern CL2. When viewed in the plane, the insulating patterns SP may be disposed inside the first conductive pattern CL1 and inside the second conductive pattern CL2.

The insulating patterns SP may include a main insulating pattern M-SP and a dummy insulating pattern D-SP. In a case where each of the main insulating pattern M-SP and the dummy insulating pattern D-SP is provided in plural, each main insulating pattern M-SP may be spaced apart from a corresponding dummy insulating pattern D-SP in the second direction DR2. FIG. 7A shows six main insulating patterns M-SP and six dummy insulating patterns D-SP spaced apart from the main insulating patterns M-SP in the second direction DR2 as a representative example. The main insulating patterns M-SP may be arranged in the first direction DR1. The dummy insulating patterns D-SP may be arranged in the first direction DR1.

As shown in FIG. 7A, the insulating patterns SP may have a circular shape when viewed in the plane, however, the shape of the insulating patterns SP in the plane are not limited to the circular shape. As an example, the insulating patterns SP may have a polygonal shape, such as a square shape, a rectangular shape, etc., or an oval shape when viewed in the plane. In addition, the shape of the insulating patterns SP should not be limited to being identical to one another.

Referring to FIGS. 7B and 7C, the end portion DL-E may be disposed on the base layer BL. The barrier layer BRL, the buffer layer BFL, and/or the first insulating layer 10 shown in FIG. 5 may extend from the display area DP-DA (refer to FIG. 4) and may be disposed on the base layer BL, but, in FIG. 7B and the following drawings, only the base layer BL is illustrated as an example.

The end portion DL-E may be disposed at the same layer as the gate G shown in FIG. 5. The end portion DL-E may be formed through the same process as the gate G. The end portion DL-E may include the same material as the gate G. However, the position of the end portion DL-E should not be limited thereto or thereby. The end portion DL-E may be disposed at the same layer, may include the same material, and may have the same stack structure as the upper electrode UE shown in FIG. 5. According to an example embodiment, some of the signal lines may be formed through the same process as the gate G (refer to FIG. 5), and the other signal lines may be formed through the same process as upper electrode UE (refer to FIG. 5).

The data line DL may be disposed at one layer and may have an integral shape, however, example embodiments of the present disclosure should not be limited thereto or thereby. One data line DL may include multiple portions disposed at different layers. For instance, the line portion DL-S may include two or more portions.

The first conductive pattern CL1 may be disposed on the end portion DL-E. The first conductive pattern CL1 may be disposed directly on the end portion DL-E, and thus, the first conductive pattern CL1 and the end portion DL-E may be electrically connected to each other. The first conductive pattern CL1 may be disposed directly on the end portion DL-E in at least a portion overlapping the dummy insulating pattern D-SP. In other words, the first conductive pattern CL1 may be disposed directly on the end portion DL-E to include a portion that overlaps the dummy insulating pattern D-SP to be disposed thereon.

The second conductive pattern CL2 may be disposed on the first conductive pattern CL1. A portion of the second conductive pattern CL2, which does not overlap the insulating pattern SP, may be in contact with the first conductive pattern CL1.

According to an example embodiment, the first conductive pattern CL1 may be formed through the same process as the first connection electrode CNE1 described with reference to FIG. 5, and the second conductive pattern CL2 may be formed through the same process as the second connection electrode CNE2 described with reference to FIG. 5. The first conductive pattern CL1 may include the same material as the first connection electrode CNE1 (refer to FIG. 5), and the second conductive pattern CL2 may include the same material as the second connection electrode CNE2 (refer to FIG. 5), however, example embodiments of the present disclosure should not be limited thereto or thereby. According to an example embodiment, the combination of connection electrodes formed through the same process as the first and second conductive patterns CL1 and CL2 may be selected in various ways depending on the stack structure of the circuit element layer DP-CL (refer to FIG. 5) as long as the first and second conductive patterns CL1 and CL2 are provided at different layers.

When viewed in the plane, the second conductive pattern CL2 may have a size greater than that of the first conductive pattern CL1, and an edge of the second conductive pattern CL2 may be positioned outside an edge of the first conductive pattern CL1 and may cover the edge of the first conductive pattern CL1, however, example embodiments of the present disclosure should not be limited thereto or thereby. On the other hand, according to an example embodiment, the second conductive pattern CL2 may have substantially the same size as the first conductive pattern CL1, and the edge of the second conductive pattern CL2 may be substantially aligned with the edge of the first conductive pattern CL1.

Each of the first conductive pattern CL1 and the second conductive pattern CL2 may have a first layer, a second layer, and a third layer, which are sequentially stacked. The second layer may have a thickness greater than a thickness of the first layer. The third layer may have a thickness smaller than the thickness of the second layer. The second layer may have a conductivity higher than a conductivity of each of the first layer and the third layer. The second layer may include a material with higher conductivity than a material included in the first and third layers. The first layer and the third layer may include the same material. The second layer may include a material different from the material included in the first and third layers. As an example, the first layer and the third layer may include titanium (Ti), and the second layer may include aluminum (Al).

Because the second layer is covered by the third layer, a surface of the second layer may be reduced or prevented from being oxidized even when the second layer is in contact with the first adhesive layer CF1 (refer to FIG. 6). In detail, the oxidation of the second layer by oxygen atoms (O) included in the first adhesive layer CF1 (refer to FIG. 6) may be reduced or prevented.

The insulating pattern SP may be disposed between the first conductive pattern CL1 and the second conductive pattern CL2. The insulating pattern SP may be disposed on the first conductive pattern CL1 and may be covered by the second conductive pattern CL2. The second conductive pattern CL2 may cover an upper surface of the insulating pattern SP.

In the present disclosure, a lower surface of the insulating pattern SP may be defined as a surface at which the insulating pattern SP is in contact with the first conductive pattern CL1. The upper surface of the insulating pattern SP may be defined as a remaining surface excluding the lower surface. The upper surface of the insulating pattern SP may be in contact with the second conductive pattern CL2.

The insulating pattern SP may have a dome shape when viewed in a cross-section, however example embodiments of the present disclosure should not be limited to thereto or thereby. According to an example embodiment, the insulating pattern SP may have a cylindrical shape, trapezoidal shape, rectangular shape, or even a reverse trapezoidal shape in the cross-section.

The insulating pattern SP may include a polymer. The insulating pattern SP may include a thermosetting polymer, however, the insulating pattern SP should not be limited to the thermosetting polymer. According to an example embodiment, the insulating pattern SP may also include a thermoplastic polymer.

The insulating pattern SP may be formed through the same process as the fifth insulating layer 50 (refer to FIG. 5). Accordingly, no additional process may be needed to form the insulating pattern SP, however, example embodiments of the present disclosure should not be limited thereto or thereby. According to an example embodiment, the combination of connection electrodes formed through the same process as the first and second conductive patterns CL1 and CL2 may be selected in various ways depending on the stack structure of the circuit element layer DP-CL (refer to FIG. 5), and thus, the insulating layer formed through the same process as the insulating pattern SP may also be selected in various ways.

Portions of the second conductive pattern CL2, which cover the insulating pattern SP, may protrude from the first conductive pattern CL1 in a thickness direction (e.g., the third direction DR3) relative to other portions of the second conductive pattern CL2. The most protruding top portion of the second conductive pattern CL2 may be defined as a protruding portion M-PK or D-PK. In detail, among the portions of the second conductive pattern CL2 that cover the main insulating pattern M-SP, the most protruding top portion may be defined as a main protruding portion M-PK. Among the portions of the second conductive pattern CL2 that cover the dummy insulating pattern D-SP, the most protruding top portion may be defined as a dummy protruding portion D-PK. In other words, the second conductive pattern CL2 may include a main protruding portion M-PK and a dummy protruding portion D-PK. The main protruding portion M-PK may be a portion of the second conductive pattern CL2 that is disposed on the main insulating pattern M-SP and protrudes in the thickness direction, and the dummy protruding portion D-PK may be a portion of the second conductive pattern CL2 that is disposed on the dummy insulating pattern D-SP and protrudes in the thickness direction.

The main protruding portion M-PK and the dummy protruding portion D-PK may be arranged so as to have a step difference d_{PK}. The step difference d_{PK} may refer to a difference in height in the thickness direction (e.g., the third direction DR3). The step difference d_{PK} between the main protruding portion M-PK and the dummy protruding portion D-PK may be greater than or equal to about 0.3 μm. As an example, the step difference d_{PK} between the main protruding portion M-PK and the dummy protruding portion D-PK may be in a range from about 0.3 μm to about 2 μm. In other words, the step difference d_{PK} in the thickness direction between a peak of the main protruding portion M-PK and a peak of the dummy protruding portion D-PK may be greater than or equal to about 0.3 μm, or may be in a range from about 0.3 μm to about 2 μms.

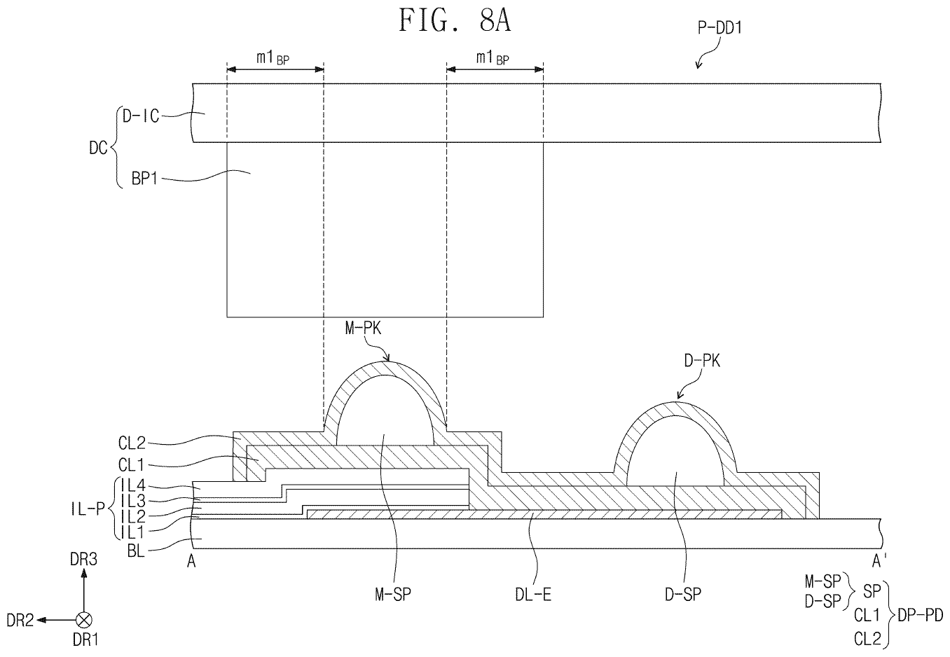

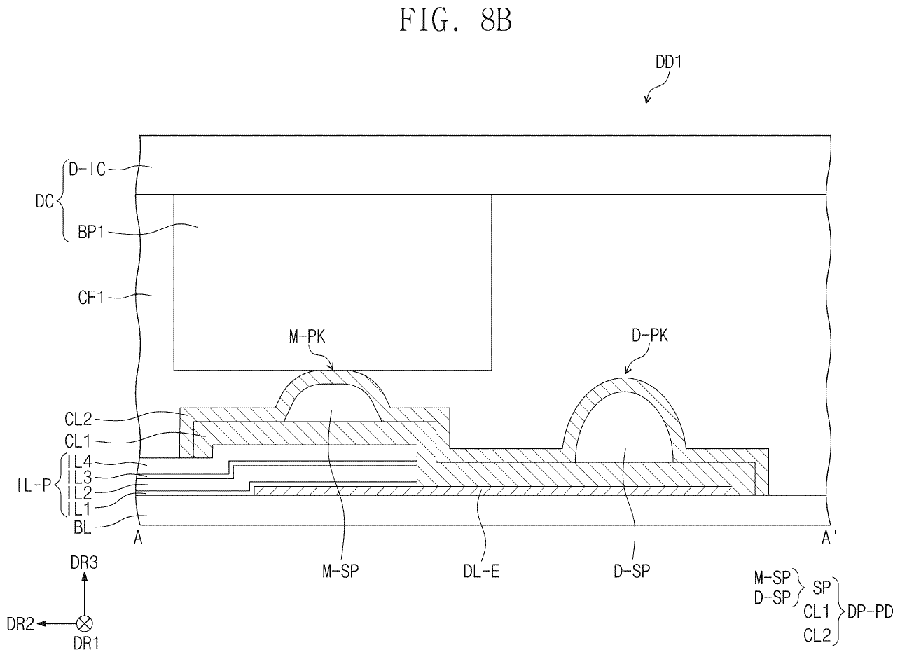

Because the step difference d_{PK} occurs between the main protruding portion M-PK and the dummy protruding portion D-PK, even if the signal pad DP-PD includes the dummy insulating pattern D-SP, it is possible to allow sufficient or improved process margin m1_{BP} (refer to FIG. 8A) of a first bump BP1 (refer to FIGS. 8A and 8B) when designing the first bump BP1 (refer to FIGS. 8A and 8B) for a first bonding process. The first bonding process and the process margin m1_{BP} (refer to FIG. 8A) will be described in detail with reference to FIGS. 8A and 8B.

The step difference d_{PK} between the main protruding portion M-PK and the dummy protruding portion D-PK may be formed by a pad insulating layer IL-P disposed between the end portion DL-E and the first conductive pattern CL1. The pad insulating layer IL-P may include at least one insulating layer. The pad insulating layer IL-P may include a plurality of insulating layers IL1, IL2, IL3, and IL4, and FIG. 7B shows four insulating layers IL1, IL2, IL3, and IL4 as a representative example. However, the number of the insulating layers included in the pad insulating layer IL-P should not be limited to four. The step difference d_{PK} between the main protruding portion M-PK and the dummy protruding portion D-PK may be changed depending on the number of the insulating layers included in the pad insulating layer IL-P or a thickness of each of the insulating layers. The insulating layers included in the pad insulating layer IL-P may correspond to one of the insulating layers of the circuit element layer DP-CL (refer to FIG. 5) disposed in the display area DP-DA (refer to FIG. 5).

According to an example embodiment, a pad conductive layer ML-P may further be disposed between the end portion DL-E and the first conductive pattern CL1. The pad conductive layer ML-P may include at least one conductive layer. The conductive layer may be a metal layer. The pad conductive layer ML-P may include a plurality of conductive layers ML1 and ML2, and FIG. 7C shows two conductive layers ML1 and ML2 as a representative example. However, the number of the conductive layers included in the pad conductive layer ML-P should not be limited to two. The conductive layers ML1 and ML2 included in the pad conductive layer ML-P may be disposed between the insulating layers IL1, IL2, IL3, and IL4. The step difference d_{PK} between the main protruding portion M-PK and the dummy protruding portion D-PK may be changed depending on not only the pad insulating layer IL-P but also the number of the conductive layers of the pad conductive layer ML-P, or a thickness of each of the conductive layers. The conductive layers included in the pad conductive layer ML-P may correspond to some of the conductive layers of the circuit element layer DP-CL (refer to FIG. 5) disposed in the display area DP-DA (refer to FIG. 5), respectively.

When viewed in the plane, the signal pad DP-PD may include a first portion (alternatively, a first pad portion) and a second portion (alternatively, a second pad portion). In detail, the first portion may refer to an area in which the main insulating pattern M-SP is disposed. The first portion may refer to the area overlapping the main insulating pattern M-SP and a peripheral area surrounding the area overlapping the main insulating pattern M-SP. The second portion may refer to an area in which the dummy insulating pattern D-SP is disposed. The second portion may refer to the area overlapping the dummy insulating pattern D-SP and a peripheral area surrounding the area overlapping the dummy insulating pattern D-SP.

The pad insulating layer IL-P may be disposed at the first portion of the signal pad DP-PD. According to an example embodiment, the pad insulating layer IL-P and the pad conductive layer ML-P may be disposed at the first portion of the signal pad DP-PD. On the other hand, the pad insulating layer IL-P and the pad conductive layer ML-P may not be disposed at the second portion of the signal pad DP-PD. That is, the first conductive pattern CL1 may be disposed directly on the end portion DL-E in the second portion of the signal pad DP-PD. Because the pad insulating layer IL-P or both the pad insulating layer IL-P and the pad conductive layer ML-P are disposed only at the first portion of the signal pad DP-PD, the step difference d_{PK} may be formed between the main protruding portion M-PK and the dummy protruding portion D-PK.

In addition to the main protruding portion M-PK and the dummy protruding portion D-PK, a step difference may be formed in layers disposed on the end portion DL-E due to the pad insulating layer IL-P or both the pad insulating layer IL-P and the pad conductive layer ML-P. The main insulating pattern M-SP may include a first lower surface that is in contact with the first conductive pattern CL1, and the dummy insulating pattern D-SP may include a second lower surface that is in contact with the first conductive pattern CL1. Due to the pad insulating layer IL-P or both the pad insulating layer IL-P and the pad conductive layer ML-P, the first lower surface and the second lower surface may be arranged so as to have the step difference. In the present disclosure, the step difference may refer to a difference in height in the thickness direction (e.g., the third direction DR3). As an example, the step difference in the thickness direction between the first lower surface and the second lower surface may be greater than or equal to about 0.3 μm. In some example embodiments, the main insulating pattern M-SP may have substantially the same thickness as the dummy insulating pattern D-SP. In some example embodiments, the main insulating pattern M-SP may have a thickness smaller than a thickness of the dummy insulating pattern D-SP.

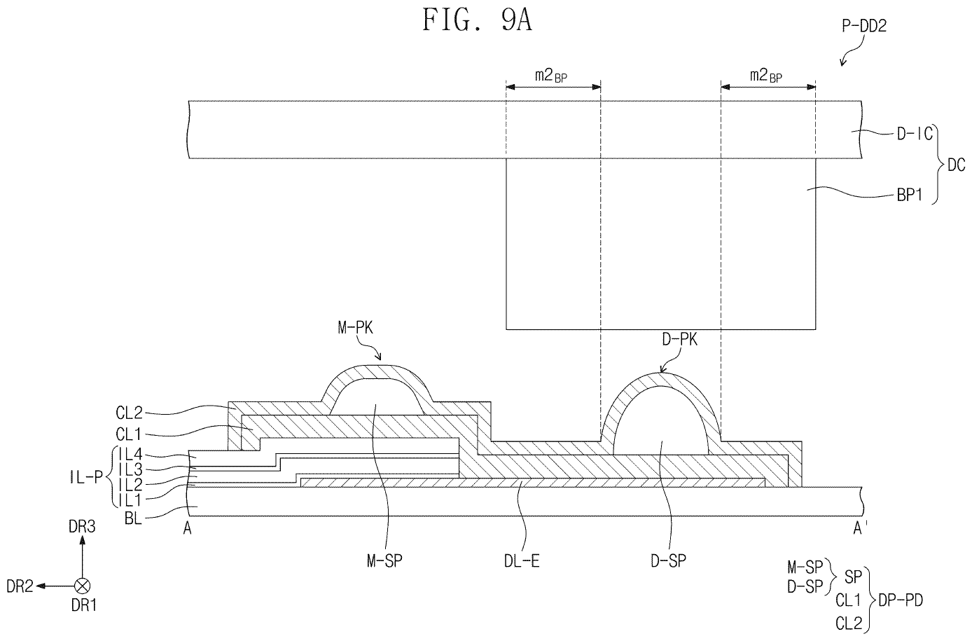

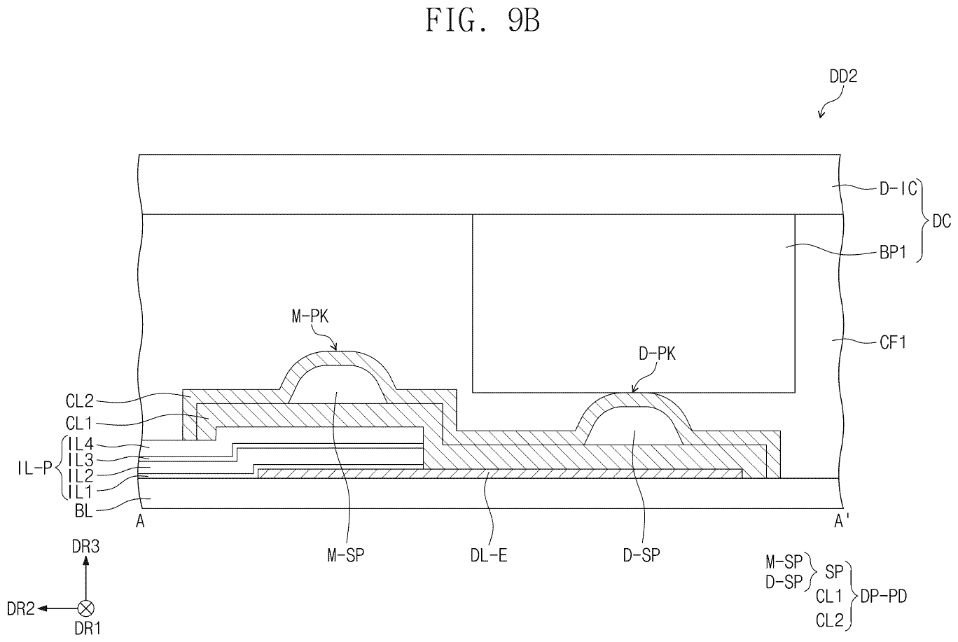

FIG. 8A is a schematic cross-sectional view of a structure of a preliminary display device P-DD1 before a bonding process, according to an example embodiment of the present disclosure. FIG. 8B is a schematic cross-sectional view of a structure of the display device DD1 after the bonding process, according to an example embodiment of the present disclosure. FIG. 9A is a schematic cross-sectional view of a structure of a preliminary display device P-DD2 before a bonding process, according to an example embodiment of the present disclosure. FIG. 9B is a schematic cross-sectional view of a structure of the display device DD2 after the bonding process, according to an example embodiment of the present disclosure.

FIGS. 8A and 8B schematically show the first bonding process, and FIGS. 9A and 9B schematically show a second bonding process. The first bonding process may refer to an initial process. The second bonding process may refer to a rework process (e.g., a re-bonding process) performed when a defect is detected during the initial process. The display devices DD1 and DD2 of FIGS. 8B and 9B may correspond to the example embodiments of the display device DD described with reference to FIGS. 1 to 6. FIGS. 8B and 9B show a driving chip DC as the example of an electronic component. In FIGS. 8B and 9B, a structure in which a first bump BP1 among the chip bump electrodes DC-BP (refer to FIG. 6) of the driving chip DC is in contact with the first pad PD1 (refer to FIG. 6) is shown. The first pad PD1 (refer to FIG. 6) is shown as a signal pad DP-PD.

FIG. 8A is a cross-sectional view showing a portion of a preliminary display device P-DD1 before the first bonding process. FIG. 8A shows a cross-section of the preliminary display device P-DD1, which corresponds to the line A-A′ of FIG. 7A. In the first bonding process, the first bump BP1 may be disposed to correspond to a main insulating pattern M-SP. In some example embodiments, the first bump BP1 may be disposed to correspond to a portion of a dummy insulating pattern D-SP as well as the main insulating pattern M-SP.

FIG. 8B is a cross-sectional view showing a portion of the display device DD1 obtained after the first bonding process for the preliminary display device P-DD1. FIG. 8B shows a cross-section of the display device DD1, which corresponds to the line A-A′ of FIG. 7A. The driving chip DC and the signal pad DP-PD may be bonded to each other by a first adhesive layer CF1. The first bump BP1 may overlap the main insulating pattern M-SP. The first bump BP1 may be electrically connected to a main protruding portion M-PK. The main insulating pattern M-SP and a portion of a second conductive pattern CL2, which is disposed on the main insulating pattern M-SP, may be deformed into a pressed shape by a pressing process of the first bonding process. The height of the main protruding portion M-PK may be lowered by about 0.3 μm in the pressing direction during the pressing process.

As shown in FIGS. 7B and 7C, because the main protruding portion M-PK and the dummy protruding portion D-PK are arranged so as to have the step difference d_{PK}, it is possible to allow sufficient or improved process margin m1_{BP} of the first bump BP1 when designing the first bump BP1 for the first bonding process even if the signal pad DP-PD includes the dummy insulating pattern D-SP. Different from the present example embodiment, in a case where the step difference d_{PK} does not exist between the main protruding portion M-PK and the dummy protruding portion D-PK, the first bump BP1 for the first bonding process may only be designed with a narrow margin within a range that does not overlap the dummy insulating pattern D-SP.

FIG. 9A is a cross-sectional view showing a portion of a preliminary display device P-DD2 before the second bonding process. FIG. 9A shows a cross-section of the preliminary display device P-DD2, which corresponds to the line A-A′ of FIG. 7A. In the second bonding process, the first bump BP1 may be disposed to correspond to a dummy insulating pattern D-SP. A main insulating pattern M-SP and the portion of the second conductive pattern CL2, which is disposed on the main insulating pattern M-SP, may be deformed into the pressed shape by the first bonding process.

FIG. 9B is a cross-sectional view showing a portion of the display device DD2 obtained after the second bonding process for the preliminary display device PDD2. FIG. 9B shows a cross-section of the display device DD2, which corresponds to the line A-A′ of FIG. 7A. The driving chip DC and the signal pad DP-PD may be bonded to each other by a first adhesive layer CF1. The first bump BP1 may overlap the dummy insulating pattern D-SP. The bump first BP1 may be electrically connected to the dummy protruding portion D-PK. The dummy insulating pattern D-SP and a portion of the second conductive pattern CL2, which is disposed on the dummy insulating pattern D-SP, may be deformed into a pressed shape by a pressing process of the second bonding process.

A process margin m2_{BP} of the first bump BP1 in the second bonding process may be narrower than the process margin m1_{BP} of the first bump BP1 in the first bonding process. The process margin m2_{BP} of the first bump BP1 in the second bonding process may be designed with a range that does not overlap the main insulating pattern M-SP.

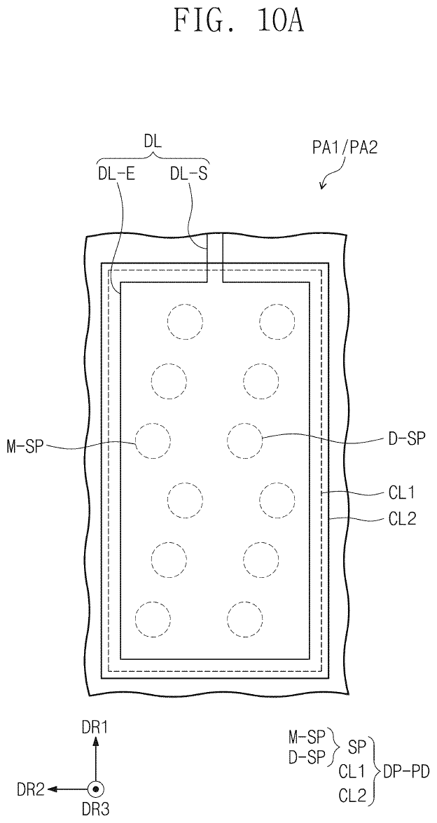

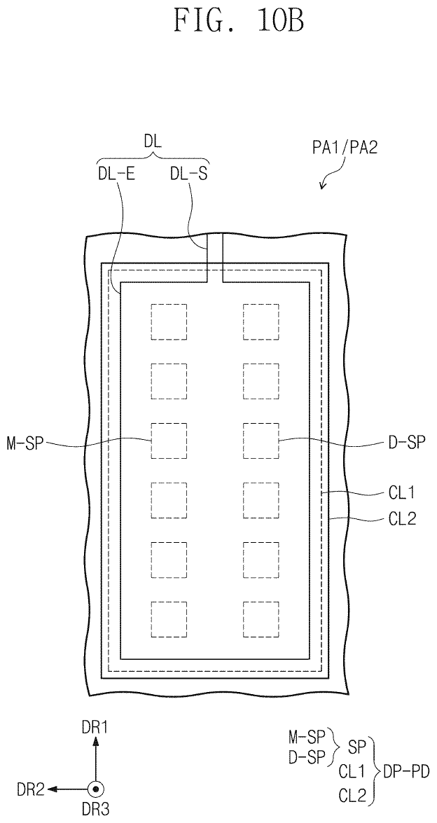

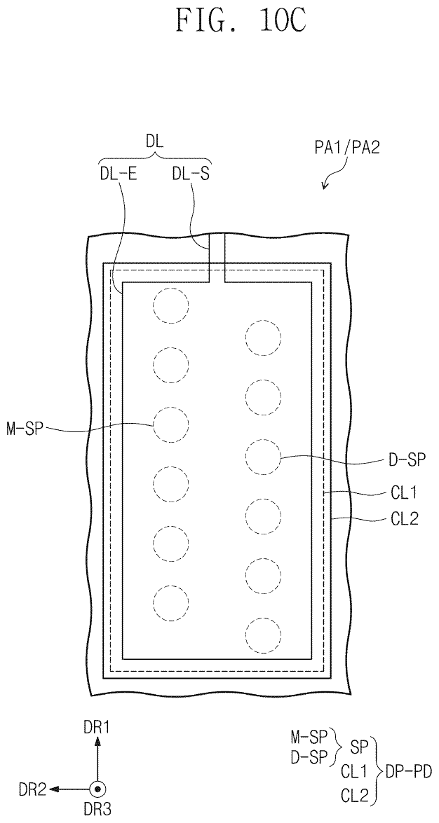

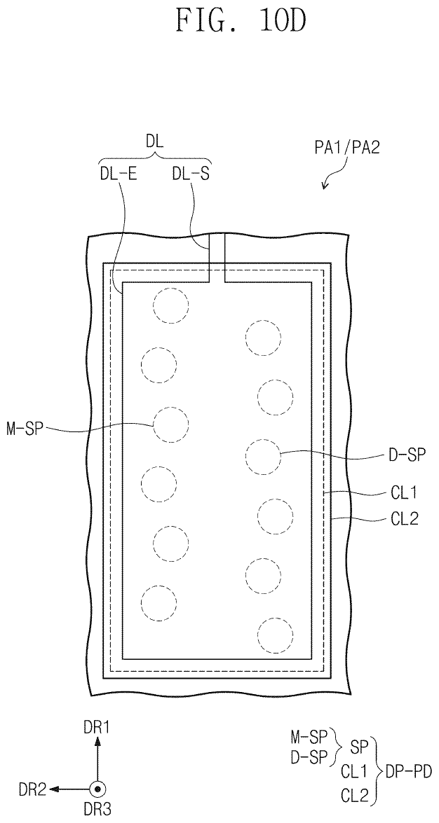

FIGS. 10A to 10D are plan views of pad areas PA1 and PA2 according to some example embodiments of the present disclosure.

Referring to FIG. 10A, centers of some main insulating patterns M-SP may be different from each other when viewed in the first direction DR1. Further, centers of some dummy insulating patterns D-SP may be different from each other when viewed in the first direction DR1.

When viewed in the first direction DR1, the main insulating pattern M-SP, which is positioned closest to the dummy insulating patterns D-SP among the main insulating patterns M-SP, and the dummy insulating pattern D-SP, which is positioned closest to the main insulating patterns M-SP among the dummy insulating patterns D-SP, may be spaced apart from each other in the second direction DR2.

Referring to FIG. 10B, each of insulating patterns SP may have a square shape when viewed in the plane. However, the shape of the insulating patterns SP in the plane should not be limited to the square and may have a polygonal shape other than the square shape.

Referring to FIG. 10C, when viewed in the second direction DR2, a center of a main insulating pattern M-SP may be different from a center of a dummy insulating pattern D-SP. The main insulating pattern M-SP and the dummy insulating pattern D-SP corresponding to the main insulating pattern M-SP may be spaced apart from each other in the first direction DR1.

Referring to FIG. 10D, centers of some main insulating patterns M-SP may be different from each other when viewed in the first direction DR1. Further, centers of some dummy insulating patterns D-SP may be different from each other when viewed in the first direction DR1. Also, when viewed in the second direction DR2, the centers of the main insulating pattern M-SP and corresponding ones of the centers of the dummy insulating patterns D-SP may differ from each other.

Because the display device DD of the present disclosure does not include the conductive balls, it is possible to reduce or prevent a short-circuit fault caused by the conductive balls and/or a conduction failure occurring when the conductive balls are not placed between the signal pad DP-PD and the bump electrode even when the signal pads DP-PD are densely packed. Therefore, the display panel with relatively high resolution may be implemented.

Because the display device DD of the present disclosure includes the main insulating pattern M-SP and the dummy insulating pattern D-SP, even if the second conductive pattern CL2 disposed on the main insulating pattern M-SP and the main insulating pattern M-SP are deformed after the initial bonding process, the rework process (e.g., the re-bonding process) may be performed using the dummy insulating pattern D-SP for products deemed defective.

Because the main protruding portion M-PK and the dummy protruding portion D-PK are arranged to have the step difference d_{PK} in the display device DD of some example embodiments of the present disclosure, the process margin m1_{BP} of the first bump BP1 for the first bonding process may be designed with sufficient tolerance. Because the process margin m2_{BP} of the first bump BP1 needs to be designed more narrowly only for the products deemed defective and thus desiring the rework process, a process efficiency may be improved.

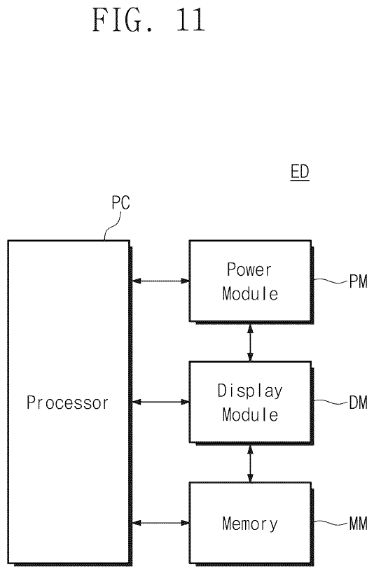

FIG. 11 is a block diagram of an electronic device ED according to an example embodiment of the present disclosure.

Referring to FIG. 11, the electronic device ED may include a display module DM, a processor PC, a memory MM, and a power module PM.

The processor PC may include at least one of a central processing unit (CPU), an application processor (AP), a graphics processing unit (GPU), a communication processor (CP), an image signal processor (ISP), or a controller.

The memory MM may store data information desired for the operation of the processor PC or the display module DM. When the processor PC executes an application stored in the memory MM, an image data signal and/or an input control signal may be transmitted to the display module DM, and the display module DM may process the received signals to output image information through a display screen.

The power module PM may include a power supply module, such as a power adapter or a battery device, and a power conversion module that converts power supplied by the power supply module to generate power desired for the operation of the electronic device ED.

At least one of components of the electronic device ED may be included in the display device DD (refer to FIG. 1) according to some example embodiments. In addition, among individual modules that are functionally included within a single module, some may be included in the display device DD (refer to FIG. 1) while others may be provided separately from the display device DD (refer to FIG. 1). As an example, the display device DD (refer to FIG. 1) may include the display module DM. The processor PC, the memory MM, and the power module PM may be provided as separate devices within the electronic device ED and may not be included in the display device DD (refer to FIG. 1).

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

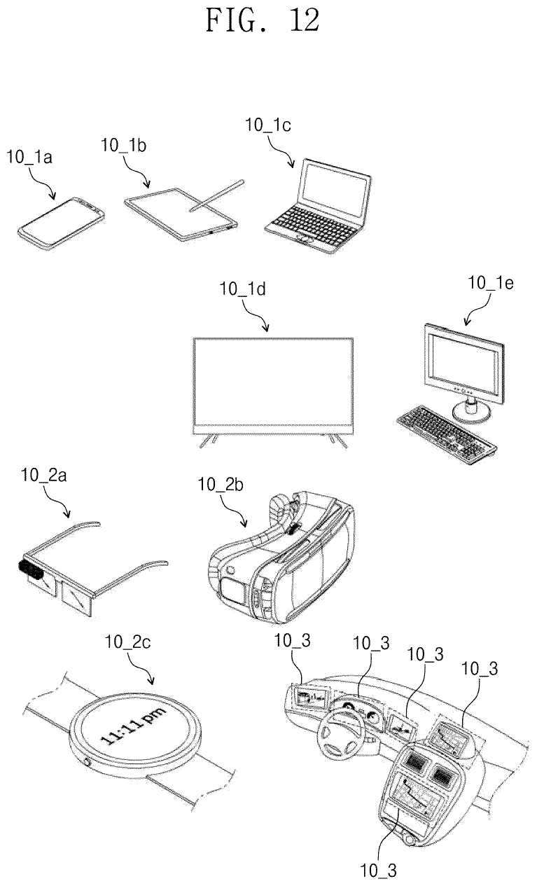

FIG. 12 is a schematic view of various electronic devices according to some example embodiments of the present disclosure.

Referring to FIG. 12, various electronic devices ED (refer to FIG. 11) to which the display device DD (refer to FIG. 1) according to some example embodiments is applied may include an electronic device to display images, such as a smartphone 10_1a, a tablet PC 10_1b, a laptop computer 10_1c, a television 10_1d, a desktop monitor 10_1e, etc., a wearable electronic device including a display module, such as a smart glasses 10_2a, a head-mounted display 10_2b, a smartwatch 10_2c, etc., or an in-vehicle electronic device 10_3 including a display module, such as an instrument panel, a center fascia, a dashboard-mounted center information display (CID), or a room mirror display.

Although some example embodiments of the present disclosure have been described, it is understood that example embodiments of the present disclosure are not limited to these example embodiments but various changes and modifications can be made by one ordinary skilled in the art within the spirit and scope of the present disclosure as hereinafter claimed. Therefore, the disclosed subject matter should not be limited to any single example embodiment described herein, and the scope of the present inventive concepts should be determined according to the attached claims.

What is claimed is:

1. A display panel comprising:
a pixel;
a signal line electrically connected to the pixel; and
a signal pad connected to the signal line, the signal pad comprising
a first conductive pattern connected to a portion of the signal line,
a second conductive pattern on the first conductive pattern, and
an insulating pattern between the first conductive pattern and the second conductive pattern, the insulating pattern comprising
a main insulating pattern, and
a dummy insulating pattern spaced apart from the main insulating pattern in a first direction,
wherein the second conductive pattern includes a main protruding portion and a dummy protruding portion, the main protruding portion being a first portion of the second conductive pattern that is on the main insulating pattern and protrudes in a thickness direction, the dummy protruding portion being a second portion of the second conductive pattern that is on the dummy insulating pattern and protrudes in the thickness direction, and
a first step difference in the thickness direction between a first peak of the main protruding portion and a second peak of the dummy protruding portion is greater than or equal to 0.3 micrometers.

2. The display panel of claim 1, wherein
the main insulating pattern comprises a first lower surface that is in contact with the first conductive pattern,
the dummy insulating pattern comprises a second lower surface that is in contact with the first conductive pattern, and
a second step difference in the thickness direction between the first lower surface and the second lower surface is greater than or equal to 0.3 micrometers.

3. The display panel of claim 1, wherein
the signal pad comprises a first pad portion including the main insulating pattern and a second pad portion including the dummy insulating pattern,
at least one insulating layer is between the portion of the signal line and the first conductive pattern at the first pad portion, and
the first conductive pattern is directly on the portion of the signal line at the second pad portion.

4. The display panel of claim 3, further comprising:
at least one conductive layer between the portion of the signal line and the first conductive pattern at the first pad portion.

5. The display panel of claim 1, wherein the main insulating pattern and the dummy insulating pattern are inside the first conductive pattern when viewed in a plane.

6. The display panel of claim 1, wherein the main insulating pattern and the dummy insulating pattern are covered by the second conductive pattern.

7. The display panel of claim 1, wherein
each of the first and second conductive patterns comprises a first layer, a second layer on the first layer, and a third layer on the second layer, and
a conductivity of the second layer is greater than a conductivity of the first layer and a conductivity of the third layer.

8. The display panel of claim 1, wherein the insulating pattern comprises a polymer.

9. An electronic device comprising:
a display panel comprising a pixel, a signal line electrically connected to the pixel, and a signal pad connected to the signal line;
an electronic component comprising a bump electrode and electrically connected to the display panel; and
an adhesive layer attaching the electronic component to the display panel, the signal pad comprising
a first conductive pattern connected to a portion of the signal line,
a second conductive pattern on the first conductive pattern, and
an insulating pattern between the first conductive pattern and the second conductive pattern, the insulating pattern comprising
a main insulating pattern, and
a dummy insulating pattern spaced apart from the main insulating pattern in a first direction,
wherein the main insulating pattern comprises a first lower surface that is in contact with the first conductive pattern,
the dummy insulating pattern comprises a second lower surface that is in contact with the first conductive pattern, and
a step difference in a thickness direction of the insulating pattern between the first lower surface and the second lower surface is greater than or equal to 0.3 micrometers.

10. The electronic device of claim 9, wherein
the signal pad comprises a first pad portion including the main insulating pattern and a second pad portion including the dummy insulating pattern,
at least one insulating layer is between the portion of the signal line and the first conductive pattern at the first pad portion, and
the first conductive pattern is directly on the portion of the signal line at the second pad portion.

11. The electronic device of claim 10, further comprising:
at least one conductive layer between the portion of the signal line and the first conductive pattern at the first pad portion.

12. The electronic device of claim 9, wherein the second conductive pattern includes a main protruding portion and a dummy protruding portion, the main protruding portion being a first portion of the second conductive pattern that is on the main insulating pattern and protrudes in the thickness direction, the dummy protruding portion being a second portion of the second conductive pattern that is on the dummy insulating pattern and protrudes in the thickness direction.

13. The electronic device of claim 12, wherein
the bump electrode overlaps the main insulating pattern when viewed in a plane,
the bump electrode is in contact with the main protruding portion and is electrically connected to the main protruding portion, and
the bump electrode is not in contact with the dummy protruding portion.

14. The electronic device of claim 13, wherein the bump electrode overlaps at least a portion of the dummy insulating pattern when viewed in the plane.

15. The electronic device of claim 13, wherein the main insulating pattern has a thickness smaller than a thickness of the dummy insulating pattern.

16. The electronic device of claim 12, wherein
the bump electrode does not overlap the main insulating pattern and overlaps the dummy insulating pattern when viewed in a plane,
the bump electrode is not in contact with the main protruding portion, and
the bump electrode is in contact with the dummy protruding portion and is electrically connected to the dummy protruding portion.

17. The electronic device of claim 16, wherein the main insulating pattern has a same thickness as a thickness of the dummy insulating pattern.

18. The electronic device of claim 9, wherein the main insulating pattern and the dummy insulating pattern are inside the first conductive pattern when viewed in a plane.

19. The electronic device of claim 9, wherein the main insulating pattern and the dummy insulating pattern are covered by the second conductive pattern.

20. The electronic device of claim 9, wherein the insulating pattern comprises a polymer.
